(19) United States
(12) Patent Application Publication
(10) Pub. No.: US 2020/0230750 A1
(43) Pub. Date: Jul. 23, 2020

(54) LEAD-FREE SOLDER PASTE FOR THERMAL VIA FILLING

(71) Applicant: Indium Corporation, Utica, NY (US)

(72) Inventors: Ning-Cheng Lee, Utica, NY (US); Runsheng Mao, Utica, NY (US)

(21) Appl. No.: 16/251,481

(22) Filed: Jan. 18, 2019

(51) Int. Cl. B23K 35/02; B23K 35/26; B23K 35/30; H05K 3/34

(52) U.S. Cl. CPC B23K 35/0244; B23K 35/26; H05K 2201/0215; H05K 3/3484; B23K 35/302

(57) ABSTRACT

Implementations of the disclosure are directed to a thermal via filling solder paste that exhibits little to no volume loss during reflow. The solder paste may include a solder powder such as tin-silver-copper alloy, a high melting temperature powder (e.g., a copper powder) having a higher melting temperature than the solder powder, and flux. The high melting temperature powder may be configured to have a melting temperature significantly higher than the solder powder. During reflow, the solder powder may melt and wet to the high melting temperature powder, forming intermetallic compounds that keep the via holes filled during and after reflow soldering.

### DESCRIPTION OF THE RELATED ART

The thermal performance of a printed circuit board (PCB) assembly is an important quality factor in electronic packaging. Often, the PCB substrate layer has the highest thermal resistance in the entire thermal path in the PCB assembly. Accordingly, minimizing the thermal resistance of the PCB substrate layer may provide the greatest benefit for heat dispassion.

One approach for reducing the thermal resistance of the PCB substrate layer is to add a thermal via. In a PCB, a vertical interconnect access or via may refer to a hole that provides an electrical connection between two or more layers of a PCB. The hole may be made conductive by electroplating, or by lining it with a tube or rivet. A via may be implemented as a through hole exposed on both sides of the board, a blind via hole exposed on one side of the board, or a buried via hole that connects internal layers without being exposed to either surface of the board.

A thermal via may refer to a via that provides a thermal path for heat flow away from the PCB substrate layer, due to the high thermal conductivity material used in the via compared to the rest of the substrate. Adding one or more thermal vias in a substrate layer may reduce thermal resistance in the PCB substrate layer, preventing overheating of the PCB assembly components. Thermal vias may be filled with a via filling material that is electrically conductive or nonconductive. The filling of thermal vias may be realized by technologies such as copper plating, nanomaterial sintering, thermal paste curing, and the like.

### BRIEF SUMMARY OF EMBODIMENTS

Implementations of the disclosure describe a thermal via filling solder paste that exhibits little to no volume loss during reflow soldering.

In one embodiment, a solder paste includes: a solder powder; particles having a higher melting temperature than a soldering temperature of the solder paste, where the solder paste has a volume ratio of solder powder to high melting temperature particles between 5:1 and 1:1.5; and flux. The solder powder may comprise Bi, a Bi alloy, Sn, a Sn alloy, In, or an In alloy, and the particles may comprise copper or copper-alloy particles, or nickel or nickel-alloy particles. During reflow, the solder powder may melt and wet to the particles (e.g., copper or copper-alloy powder) to form an intermetallic compound comprising copper. In particular implementations, the solder powder comprises an Sn—Ag—Cu alloy or a Bi—Sn alloy.

In some implementations, the flux is an epoxy flux, where during reflow, the epoxy flux cures at a temperature above a melting temperature of the solder powder. In some instances, the epoxy flux may cure after the solder powder melts and wets to the particles (e.g., copper or copper-alloy powder) to form an intermetallic compound.

In some implementations, the solder paste has a volume ratio of solder powder to high melting temperature particles between 5:1 and 2:1.

In one embodiment, a method includes: filling a via hole of a printed circuit board (PCB) substrate with a solder paste, the solder paste comprising: a solder powder, particles having a higher melting temperature than a soldering temperature of the solder paste, and flux; and reflowing the PCB substrate, where during reflow, the solder powder melts and wets to the particles to form an intermetallic compound. In some implementations, the method further includes: forming the via hole in the PCB substrate. The via hole may be a via through hole or some other type of via hole.

In one embodiment, a PCB substrate includes: a first layer; a second layer; and a via hole providing an electrical interconnection from the first layer to the second layer, where the via hole is filled with a solder joint formed by reflowing a solder paste, the solder paste including: a solder powder, particles having a higher melting temperature than a soldering temperature of the solder paste, and flux, where during reflow, the solder powder melts and wets to the particles to form an intermetallic compound.

Other features and aspects of the invention will become apparent from the following detailed description, taken in conjunction with the accompanying drawings, which illustrate, by way of example, the features in accordance with embodiments of the invention. The summary is not intended to limit the scope of the invention, which is defined solely by the claims attached hereto.

### BRIEF DESCRIPTION OF THE DRAWINGS

The technology disclosed herein, in accordance with one or more various embodiments, is described in detail with reference to the included figures. The figures are provided for purposes of illustration only and merely depict example implementations. Furthermore, it should be noted that for clarity and ease of illustration, the elements in the figures have not necessarily been drawn to scale.

FIG. 1 depicts a simplified example of a PCB substrate with solder-paste filled vias, in accordance with implementations of the disclosure.

FIG. 2 illustrates a PCB assembly, in accordance with implementations of the disclosure.

FIG. 3 is an operational flow diagram illustrating example steps of a method of forming a PCB substrate, in accordance with implementations of the disclosure.

FIG. 4 is a micrograph illustrating a cross section of a PCB via hole after reflow with a solder paste, in accordance with implementations of the disclosure.

FIG. 5 is a micrograph illustrating a cross section of a PCB via hole after reflow with a solder paste, in accordance with implementations of the disclosure.

The figures are not intended to be exhaustive or to limit the invention to the precise form disclosed. It should be understood that the invention can be practiced with modification and alteration, and that the disclosed technology be limited only by the claims and the equivalents thereof.

### DETAILED DESCRIPTION OF THE EMBODIMENTS

Some conventional solder paste compositions may not serve as a good thermal via filling material because of their composition. They contain about 50% by volume of flux and about 50% by volume solder powder. However, during a conventional solder paste reflow soldering process, the flux component of the paste may be expelled from the metal power component, leaving about 50% of the original paste volume. Accordingly, if a via is filled with conventional solder paste, the solder joint formed after reflow may only fill a portion (e.g., about 50%) of the length of the via hole (i.e., the depth of the substrate). As the solder joint does not reach both surfaces of the PCB substrate, the solder joint filled thermal via may not transfer heat efficiently.

In view of the foregoing, it would be desirable to use a solder paste for thermal via filling such that, during reflow, the solder paste deposited into the thermal via does not reduce in volume, thereby forming a solder joint that reaches both surfaces of the PCB substrate. Additionally, it would be desirable to use a solder paste that forms a solder joint that exhibits a much higher melting temperature than the original reflow temperature such that the filled thermal via may maintain its physical shape during subsequent PCB board assembly processes.

To this end, various implementations of the disclosure are directed to a thermal via filling solder paste that exhibits little to no volume loss during reflow soldering. In accordance with various implementations of the disclosure, the solder paste includes a solder powder such as tin-silver-copper (SAC), a high melting temperature metallic powder (e.g., a Cu powder) having a higher melting temperature than the solder powder, and flux. The high melting temperature metallic powder may be configured to have a melting temperature significantly higher than the solder powder but still wet with the solder powder at reflow soldering temperatures. By virtue of this configuration, after a thermal via is filled with the solder paste, during reflow, the solder powder may melt and wet to the high melting temperature metallic powder, forming intermetallic compounds that keep the via holes filled during and after reflow soldering.

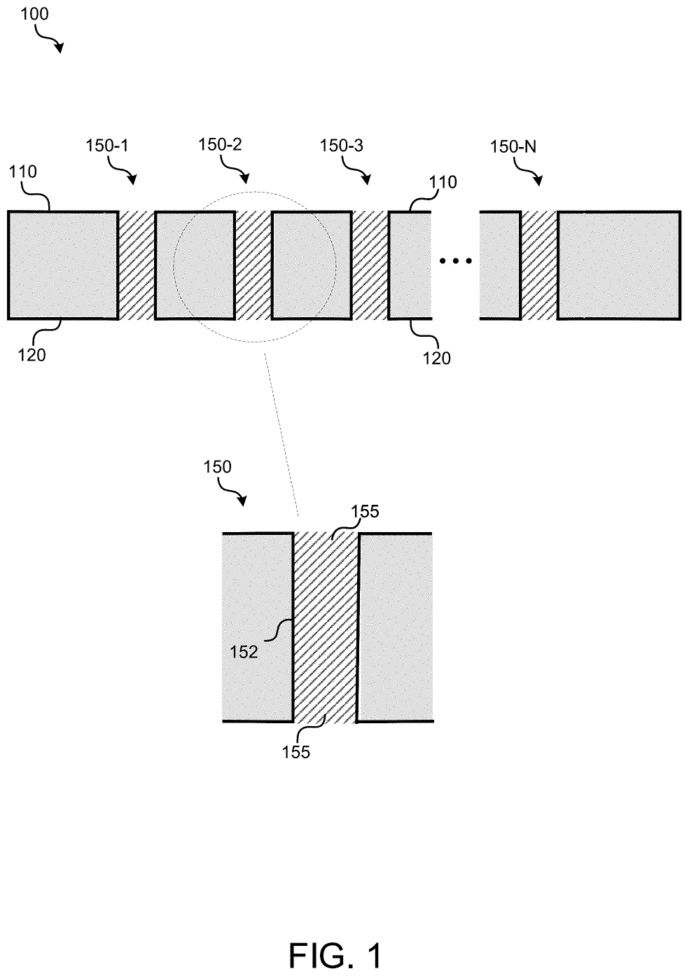

FIG. 1 depicts a simplified example of a PCB substrate 100 with solder-paste filled vias, in accordance with implementations of the disclosure. PCB substrate 100 may be made of a non-conducting material such as FR-4 which is made from woven fiberglass cloth impregnated with an epoxy resin. PCB substrate 100 may include various layers of conductive wires or traces through which electric current may flow to couple electronic components. In the illustrated example, PCB substrate 100 includes a top surface layer 110 and bottom surface layer 120. A plurality of solder-paste filled vias 150-1, 150-2, 150-3, . . . , 150-N (collectively referred to as “vias 150” and individually referred to as a “via 150”) form through holes that electrically connect top surface layer 110 to bottom surface layer 120. A via 150 may include a barrel plated with copper or some other conductive material 152, anti-pads (not shown) to provide clearance between the via and metal layer to which it is not connect, and pads to connect each end of the barrel to a component, plane or trace. Depending on the implementations, vias 150 may be via-in-pad plated over (VIPPO) structures, non-VIPPO structures, or a combination of the two types of structures.

Although filled through hole vias exposed on both sides of the PCB substrate 100 are illustrated in this example, it should be appreciated that in some implementations PCB substrate 100 may include a combination of through holes, blind holes, buried holes, or other some other type of via that provides electrical connection between internal and/or external layers of the PCB substrate. These other types of vias, in some implementations, may also be filled with the solder paste described herein. As such, in addition to top layer 110 and bottom layer 120, it should be appreciated that PCB substrate 100 may include one or more internal layers that are electrically connected using vias, pads, traces, or other components running along or through the surface of the different layers of the PCB substrate.

As illustrated, each via 150 is filled with a solder paste 155. Solder paste 155 comprises a solder powder, high melting temperature particles having a higher melting temperature than the solder powder, and flux. Solder paste 155 may form into a solder joint during a reflow process.

The solder powder may comprise a solder metal or alloy having a melting temperature such that it melts during typical reflow soldering temperatures. For example, the solder powder may be composed of a solder metal or alloy have a liquidus or melting temperature in the range of 90-450° C. In some implementations, the solder metal or alloy may be composed of bismuth (Bi), a Bi-alloy (e.g., Bi—Ag alloy, Bi—Cu alloy, Bi—Ag—Cu alloy, Bi—Sn alloy, or Bi—In alloy), tin (Sn), an Sn-alloy (e.g., an Sn—Ag alloy, Sn—Cu alloy, Sn—Ag—Cu alloy, or Sn—In alloy), indium (In), an In-alloy, or some other suitable solder alloy.

The high melting temperature particles may be wettable by the solder of the solder powder and have a melting temperature significantly higher than that of the solder powder. In particular, they may have a melting temperature greater than a soldering temperature of the solder paste. For example, the high melting temperature particles may have a melting temperature of greater than 500° C. The higher melting temperature particles may help to maintain the thermal, electrical, and/or mechanical integrity of a formed solder joint (e.g., joint formed in via) without collapse, even after subsequent exposure of the joint to the original curing/melting temperatures, or even higher temperatures.

In some implementations, the high melting temperature particles may be composed of Cu or a Cu alloy, Ni or a Ni alloy, or some combination thereof. The high melting temperature particles may be implemented in a powder form. For example, the high melting temperature particles may be implemented as a copper powder having a melting temperature of about 1085° C.

In some implementations, high melting temperature particles may have diameters that vary in the range from a few nanometers to hundreds of microns, or some combination thereof.

In some implementations, the volume ratio between the solder powder and high melting temperature particles may be between 5:1 and 1:1.5. In some implementations, the volume ratio between the solder powder and high melting temperature particles is between 5:1 and 2:1. In particular implementations, the volume ratio is about 2:1.

In some implementations, the solder paste may comprise 15-60 vol % of the solder powder, 8-36 vol % of the high melting temperature particles, and 40-60 vol % of the flux.

As noted above, the high melting temperature particles may be wettable by the solder during reflow temperatures. For example, when a thermal via is filled with a solder paste in accordance with implementations of the disclosure, and reflowed at a peak temperature of about 240-250° C., the solder powder may melt and wet to a solid powder of the high melting temperature particles to form a layer of intermetallic compound. For example, the solder powder may wet to a solid copper powder and form a layer of intermetallic compound.

With a high enough Cu powder concentration, the Cu powder may be bonded to the solder powder with an intermetallic compound bridge and form a Cu powder network. Because intermetallic compounds such as Cu₆Sn₅ typically exhibit a high melting temperature (e.g., 450° C. or higher), a copper powder network impregnated in liquid solder may form a rigid solder plug that prevents the collapse of the whole solder body during reflow. As such, by virtue of this implementation, a thermal via may be fully filled with the solder paste before and after a reflow process. The solder column, owing to the high thermal conductivity of the solder powder and copper metal, may provide a significantly reduced thermal resistance when compared to the substrate itself.

Furthermore, due to the formed copper powder network, the solid column may not collapse when reheated to a temperature above the melting temperature of the solder powder, such as 240-250° C. In implementations, this effect may best be achieved when the volume ratio of the solder powder to copper powder is between 5:1 and 1:1.5. If too much solder is used, the copper may not be enough to form a Cu-powder-network to keep the solder from collapsing. On the other hand, if too much copper powder is used, there may be insufficient solder to form an intermetallic compound bridge to bond all Cu-powder into a network, resulting in loose copper powder that may be entrapped in the solder joint, resulting in a weak solder joint.

The flux of the solder paste 155 may be a “no-clean” flux where the flux remains in the solder joint such as the one contained in Indium8.9HF or Indium10.1HF, a low residue flux, such as NC-SMQ75, or a polymer-based flux such as an epoxy flux.

In implementations of a polymeric flux, the flux may be a thermal or photonic-curable polymeric flux. The flux may contain a polymeric material with attached acid groups for fluxing. The fluxing acid groups may incorporate into the polymeric chain during polymeric curing, leaving no remaining acid groups that could contribute to corrosion during the lifetime of the solder joint. This may be in contrast to traditional solder pastes that may cause corrosion from the remaining acid groups after curing, which may be undesirable because the formation of metal oxides may weaken the solder joint over time, and damage thermal and electrical pathways.

Polymeric fluxing materials may also provide better bonding to the substrate (e.g., side walls of via) as compared to traditional fluxes. For example, traditional and low residue fluxes may leave some low molecular weight materials in contact with the substrate, which may decrease the overall integrity of a solder joint. In the case of a through-hole via on a PCB, a polymeric flux may bond to the substrate (e.g., alternating layers of glass fiber and polymer resin contained in a typical PCB), improving overall joint integrity.

Additionally, the use of a metal-containing epoxy flux may obviate the need to a plate a through-hole via with copper, which could potentially save time and money during manufacture of PCBs.

In some implementations, the flux may contain 100% curable components that do not lose mass or reduce in volume, forming a rigid solid shape after curing. In such implementations, the formation of cavities due to the loss volatiles may be minimized or eliminated, and a high thermal conductivity may be assured. A cured epoxy flux and high melting temperature particles (e.g., Cu) may contribute to the integrity of the formed solder joint, preventing both collapse of the joint and the formation of gaps at the top or bottom of the solder joint (e.g., in the case of a filled via). The cured polymer may fill voids between the solder and the high melting temperature particles to prevent collapse.

In various implementations, the solder alloy of the solder paste may be configured to melt at a lower temperature than the epoxy flux cures. In such implementations, the solder alloy and high melting temperature particles (e.g., Cu) may fuse together and form an intermetallic compound with the base metal (e.g., in the case of a metallic substrate) prior to the epoxy flux curing. For instance, a low-melting temperature solder alloy such as Bi—Sn may be utilized in such implementations.

Although implementations of the solder paste described herein have been primarily described in the context of filling thermal vias of PCB substrate, it should be appreciated that the solder paste described herein may suitable for other applications. For instance, a solder paste in accordance with the disclosure may be utilized to bridge several pads on a PCB such as a common ground or continuous racetrack formation without shrinkage of the paste. The rigid shape may be formed after curing with minimal or no electrical, thermal, and/or mechanical gaps in the trace. More generally, the solder paste described herein may be used as an alternative to conventional solder pastes to provide an electrical and/or thermal conductor (e.g., for a through-hole via on a PCB) without the gaps sometimes seen in conventional solder pastes that contain volatile components that reduce the mass and volume of the joint.

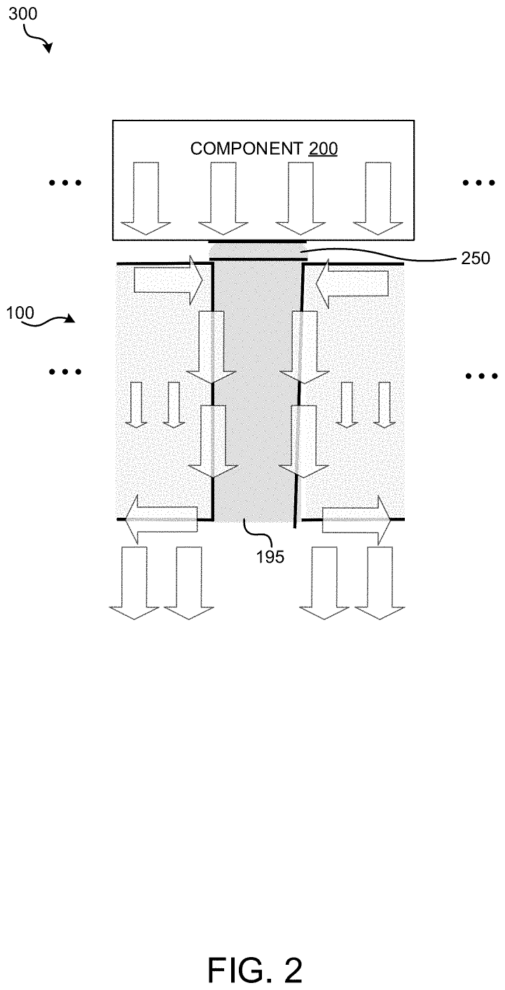

FIG. 2 illustrates a PCB assembly 300 in accordance with implementations of the disclosure. As illustrated, PCB assembly 300 includes a component 200 bonded to a PCB substrate 100 at joint 250. (e.g., a solder joint). PCB substrate includes a via filled with a solder joint 195 (e.g., formed after reflowing a solder paste in accordance with the disclosure). The arrows of FIG. 2 illustrate the heat flow from component 200 and through PCB substrate 100. As shown in this example, heat is generated uniformly on the surface of component 200 and intercepted by a thermally conductive surface of PCB substrate 100. Because of the high thermal conductivity of the metal (e.g., copper) plating the surface area near the via, most of the heat may converge to the via location. Additionally, because of the high thermal conductivity of solder joint 195 relative to the other material of PCB substrate 100, most of the heat will flow along the length of the thermally conductive via and diverge upon reaching the bottom plane of the substrate.

In embodiments, component 200 may include active electronic devices (e.g., BGA packages, chip scale packages, and Flip Chip packages); passive electronic devices (e.g., resistors, capacitors, and light emitting diodes); and non-electronic parts (e.g., electrical connectors, battery clips, heat sinks, and relays). Although the example of FIG. 2 illustrates a component 200 connected to a via-in-pad (VIPPO) pad of a via of PCB substrate 100, it should be appreciated that component 200 may be connected to PCB substrate 100 using non-VIPPO pads or a combination of VIPPO and non-VIPPO pads.

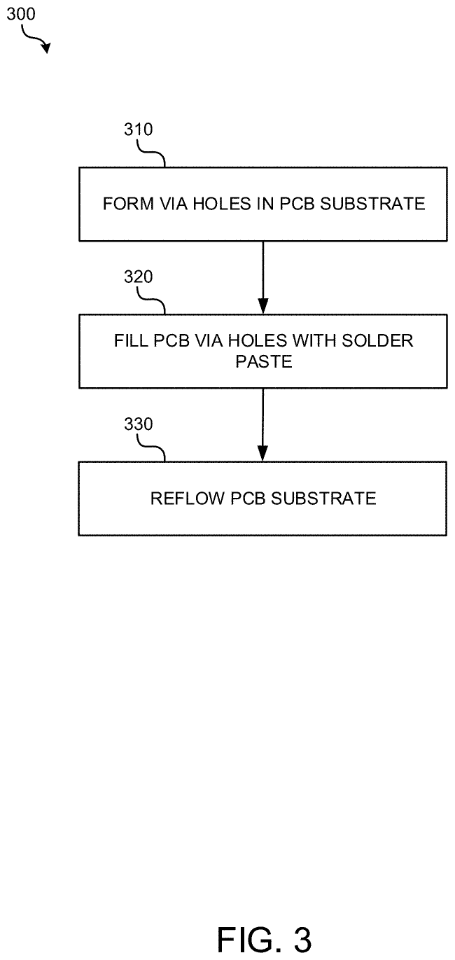

FIG. 3 is an operational flow diagram illustrating example steps of a method 300 of forming a PCB substrate, in accordance with implementations of the disclosure. For simplicity of discussion, some steps may be omitted. At operation 310, via holes are formed in a PCB substrate. For example, via holes may be drilled into the PCB substrate. The via holes may be formed in any suitable pattern or array to provide electrical connections between layers of the PCB substrate, and/or to provide a thermal path for heat flow.

At operation 320, the formed PCB via holes are filled with a solder paste comprising a solder powder, high melting temperature particles having a higher melting temperature than the solder powder, and flux. The via holes may be filled by printing or some other suitable deposition method. The solder paste may be of the composition described herein with reference to various implementations. For example, the solder powder may comprise a SAC alloy or Bi alloy, the high melting temperature particles may comprise a copper powder, and the flux may comprise an epoxy flux.

At operation 330, after filling the PCB substrate via holes with the solder paste, the PCB substrate may be reflowed to form a solder joint in the filled via. The PCB substrate may be placed in a reflow oven, and reflowed at a suitable temperature profile. During reflow, the solder may melt and wet to the high melting temperature particles, forming intermetallic compounds that keep the via holes filled during and after reflow. In some implementations, the flux of the via may cure after the solder begins to melt and fuses with the high melting temperature particles (e.g., Cu) to form an intermetallic compound.

After formation of the solder joint, the PCB substrate may be bonded to components. The formed solder joints of the vias may maintain their integrity during subsequent reflow processes.

### EXPERIMENTAL RESULTS

### Example 1: Solder Paste Using a No-Clean Flux

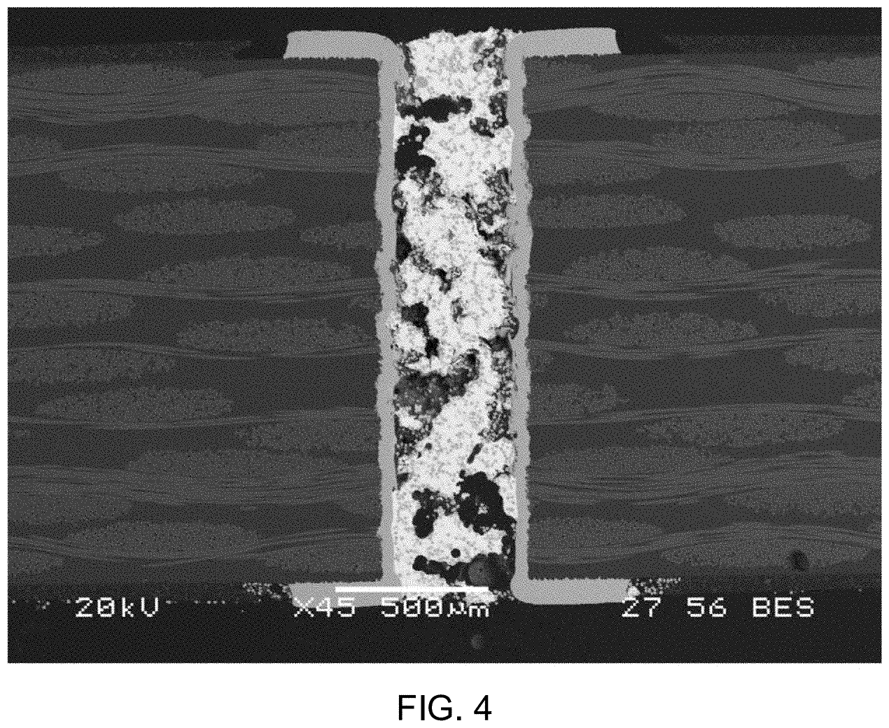

In one example, a solder paste was made by mixing 12 g Indium8.9HF flux, 58 g Sn96.5/Ag3.0/Cu0.5 (SAC305) powder, and 30 g copper powder. The volume ratio of SAC305 to copper powder was approximately 2:1. The paste was used to fill, by printing, a through-hole via of a PCB having a diameter of 14 mil. After the through-hole via was filled, the PCB was placed in a convection reflow oven with a time-temperature profile typically used to reflow SAC305 solder paste. FIG. 4 is a micrograph illustrating a cross section of the PCB via hole after reflow with the solder paste. As illustrated, the via hole is filled from top to bottom, and the solder joint body is semi-continuous. The semi-continuous solder body provided an effective thermal-conductive metal conducting path.

The same solder paste of example 1 was reflowed and then grounded to a thin-disk shape. The thermal conductivity of the solder joint was measured by a NanoFlash® instrument, which resulted in a thermal conductivity readout of 4.0 Wm⁻¹K⁻¹ at 25° C. By comparison, a conventional FR-4 substrate has an approximate thermal conductivity of 0.1 Wm⁻¹K⁻¹. As such, the solder paste may provide a significant reduction in thermal resistance when used to fill thermal vias of a PCB substrate.

When the aforementioned disk was reheated to 260° C., no collapse was observed. As such, a PCB substrate with such paste-filled thermal vias may survive the subsequent surface mount technology processing.

### Example 2: Solder Paste Using Epoxy Flux

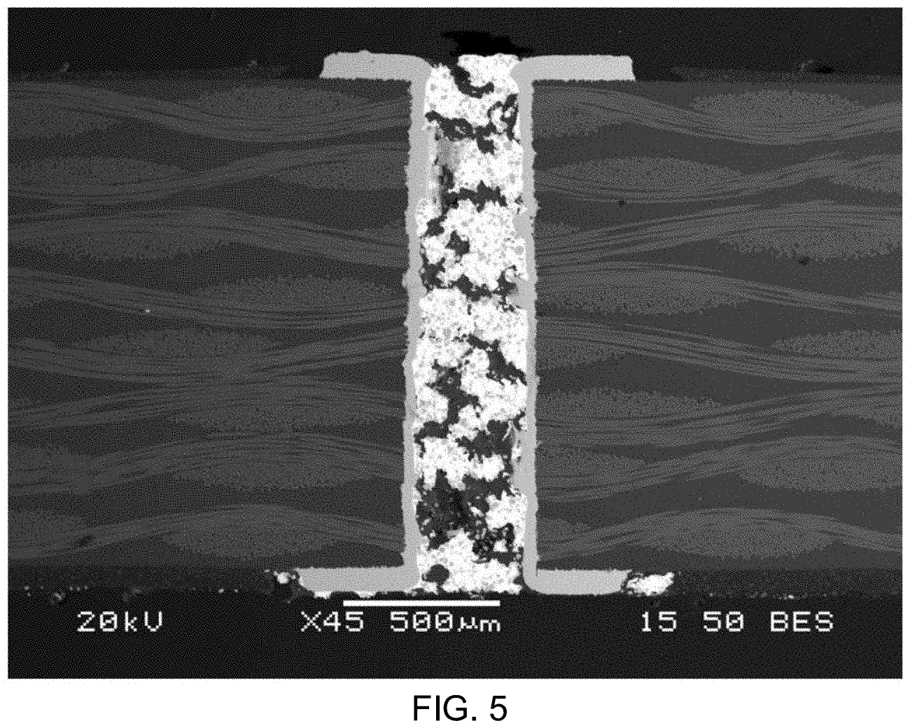

In one example, a solder paste was made by mixing 12 g epoxy flux, 58 g SAC305 powder, and 30 g copper powder. The volume ratio of SAC305 to copper powder was approximately 2:1. The paste was used to fill, by printing, a through-hole via of a PCB having a diameter of 14 mil. After the through-hole via was filled, the PCB was placed in a convection reflow oven with a time-temperature profile typically used to reflow SAC305 solder paste. FIG. 5 is a micrograph illustrating a cross section of the PCB via hole after reflow with the solder paste. As illustrated, the via hole is filled from top to bottom, and the solder joint body is semi-continuous. The semi-continuous solder body provided an effective thermal-conductive metal conducting path. In this example, by using a cured epoxy flux, fewer cavities were formed in the solder joint body. The thermal conductivity of the solder joint was measured at 8.6 Wm⁻¹K⁻¹ at 25° C., indicating a higher thermal conducting efficiency than the previous example.

While various embodiments of the disclosed technology have been described above, it should be understood that they have been presented by way of example only, and not of limitation. Likewise, the various diagrams may depict an example architectural or other configuration for the disclosed technology, which is done to aid in understanding the features and functionality that can be included in the disclosed technology. The disclosed technology is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the technology disclosed herein. Also, a multitude of different constituent module names other than those depicted herein can be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the disclosed technology is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the disclosed technology, whether or not such embodiments are described and whether or not such features are presented as being a part of a described embodiment. Thus, the breadth and scope of the technology disclosed herein should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. A solder paste, comprising:
a solder powder;
particles having a higher melting temperature than a soldering temperature of the solder paste, wherein the solder paste has a volume ratio of solder powder to high melting temperature particles between 5:1 and 1:1.5; and
flux.

2. The solder paste of claim 1, wherein the solder powder comprises Bi, a Bi alloy, Sn, a Sn alloy, In, or an In alloy, and wherein the particles comprise copper or copper-alloy particles, or nickel or nickel-alloy particles.

3. The solder paste of claim 2, wherein the particles comprise a copper or copper-alloy powder, wherein during reflow, the solder powder melts and wets to the copper or copper-alloy powder to form an intermetallic compound comprising copper.

4. The solder paste of claim 3, wherein the flux is an epoxy flux, wherein during reflow, the epoxy flux cures at a temperature above a melting temperature of the solder powder.

5. The solder paste of claim 4, wherein during reflow, the epoxy flux cures after the solder powder melts and wets to the copper or copper-alloy powder to form the intermetallic compound.

6. The solder paste of claim 5, wherein the solder powder comprises an Sn—Ag—Cu alloy.

7. The solder paste of claim 5, wherein the solder powder comprises a Bi—Sn alloy.

8. The solder paste of claim 1, wherein the solder paste has a volume ratio of solder powder to high melting temperature particles between 5:1 and 2:1.

9. The solder paste of claim 8, wherein during reflow: the solder powder melts and wets to the particles to form an intermetallic compound; and the flux cures after the solder powder melts and wets to the particles to form an intermetallic compound.

10. A method, comprising:
filling a via hole of a printed circuit board (PCB) substrate with a solder paste, the solder paste comprising: a solder powder, particles having a higher melting temperature than a soldering temperature of the solder paste, and flux; and
reflowing the PCB substrate, wherein during reflow, the solder powder melts and wets to the particles to form an intermetallic compound.

11. The method of claim 10, wherein the particles comprise copper or copper-alloy particles, or nickel or nickel-alloy particles.

12. The method of claim 11, wherein the particles comprise a copper or copper-alloy powder, wherein during reflow, the solder powder melts and wets to the copper or copper-alloy powder to form an intermetallic compound comprising copper.

13. The method of claim 10, wherein the flux is an epoxy flux, wherein during reflow, the epoxy flux cures at a temperature above a melting temperature of the solder powder.

14. The method of claim 10, wherein the solder paste has a volume ratio of solder powder to high melting temperature particles between 5:1 and 1:1.5.

15. The method of claim 14, wherein the solder paste has a volume ratio of solder powder to high melting temperature particles between 5:1 and 2:1.

16. The method of claim 10, wherein the via is a through-hole via.

17. The method of claim 11, wherein the solder powder comprises Bi, a Bi alloy, Sn, a Sn alloy, In, or an In alloy.

18. The method of claim 12, wherein the flux is a no-clean flux.

19. The method of claim 10, further comprising: forming the via hole in the PCB substrate.

20. A PCB substrate, comprising:
a first layer;
a second layer; and
a via hole providing an electrical interconnection from the first layer to the second layer, wherein the via hole is filled with a solder joint formed by reflowing a solder paste, the solder paste comprising: a solder powder, particles having a higher melting temperature than a soldering temperature of the solder paste, and flux, wherein during reflow, the solder powder melts and wets to the particles to form an intermetallic compound.

21. The PCB substrate of claim 20, wherein the particles comprise copper or copper-alloy particles, or nickel or nickel-alloy particles, wherein the solder powder comprises Bi, a Bi alloy, Sn, a Sn alloy, In, or an In alloy.

22. The PCB substrate of claim 21, wherein the particles comprise a copper or copper-alloy powder, wherein during reflow, the solder powder melts and wets to the copper or copper-alloy powder to form an intermetallic compound comprising copper.

23. The PCB substrate of claim 20, wherein the flux is an epoxy flux, wherein during reflow, the epoxy flux cures at a temperature above a melting temperature of the solder powder.

24. The PCB substrate of claim 20, wherein the solder paste has a volume ratio of solder powder to high melting temperature particles between 5:1 and 1:1.5.
